(19) United States
(12) Patent Application Publication
(10) Pub. No.: US 2022/0336221 A1
(43) Pub. Date: Oct. 20, 2022

(54) LAMINATED WAFER GRINDING METHOD

(71) Applicant: DISCO CORPORATION, Tokyo (JP)

(72) Inventor: Jaeyoung LEE, Tokyo (JP)

(21) Appl. No.: 17/657,851

(22) Filed: Apr. 4, 2022

(30) Foreign Application Priority Data
Apr. 19, 2021 (JP) 2021-070461

(51) Int. Cl. H01L 21/304; H01L 21/268; B24B 37/04

(52) U.S. Cl. CPC H01L 21/304; H01L 21/268; B24B 37/042

(57) ABSTRACT

A laminated wafer grinding method includes applying a laser beam having such a wavelength as to be transmitted through a first wafer to the first wafer along a first annular street set on the inner side of a peripheral edge of the first wafer to form a first annular modified layer, and applying the laser beam to the first wafer along at least one second street set in an annular region extending from the first street to the peripheral edge of the first wafer to form a second modified layer that partitions the annular region into two or more parts, causing a cutting blade to cut into the annular region to a predetermined depth of the first wafer to cut the annular region, and grinding a second surface side of the first wafer to thin the first wafer to a finished thickness and removing the annular region.

### BACKGROUND OF THE INVENTION

### Field of the Invention

The present invention relates to a laminated wafer grinding method of, in a laminated wafer in which a first wafer and a second wafer which are chamfered on peripheral parts on both surface sides are laminated, grinding the first wafer to thin the same.

### Description of the Related Art

When a back surface side of a semiconductor wafer (hereinafter referred to simply as a wafer) formed with a chamfered part at each peripheral part on a front surface side and the back surface side is ground, for example, to thin the wafer to a thickness of equal to or less than half the original thickness, what is generally called a knife edge (also called a sharp edge) is formed at the peripheral part of the wafer that has been thinned. When the knife edge is formed, the wafer is liable to crack starting from the knife edge, during grinding of the wafer or during transportation of the wafer. To avoid this, there has been proposed a processing method in which, at the peripheral part of the wafer, a cutting blade is made to cut from the front surface into a predetermined depth corresponding to a finished thickness, to remove the chamfered part on the front surface side by cutting (that is, to perform edge trimming), and thereafter the back surface side of the wafer is ground. In addition, there has also been proposed a method of using a laser beam of such a wavelength as to be transmitted through the wafer or using a laser beam of such a wavelength as to be absorbed in the wafer, in place of the cutting blade, to remove a peripheral part of one wafer formed with the chamfered part at the peripheral part (see, for example, Japanese Patent Laid-open No. 2006-108532).

Incidentally, in a laminated wafer in which front surfaces of two wafers (first wafer and second wafer) formed with chamfered parts at peripheral parts on the front surface side and the back surface side and formed with devices such as integrated circuits (ICs) on the front surface side are fixed by an adhesive, only the first wafer may be thinned. In this case, the back surface side of the second wafer can be held under suction by a chuck table, the back surface side of the first wafer can be exposed to the upper side, and the cutting blade can be made to cut into the peripheral part of the back surface side of the first wafer, to remove the chamfered parts on the front surface side and the back surface side of the first wafer.

However, in order to remove also the chamfered part on the front surface side in addition to the chamfered part on the back surface side, it is necessary to precisely position the lower end of the cutting blade during cutting at a boundary position between the front surface of the first wafer and the front surface of the second wafer. If the cutting blade is made to cut into even slightly deeper than the boundary position, the front surface side of the second wafer is cut. For example, in a case where a wiring layer formed of copper is provided in a peripheral marginal area on the front surface side of the second wafer, there is a problem that, when the cutting blade is made to cut into the peripheral marginal area on the front surface side of the second wafer, burr including copper would be generated.

In order to solve this problem, for example, after a modified layer is formed in the peripheral part of the first wafer by use of a laser beam of such a wavelength as to be transmitted through the wafer, the back surface side of the first wafer can be ground to thereby apply an external force to the first wafer, thereby removing the peripheral part of the first wafer. Specifically, first, in a state in which the laser beam is concentrated on a predetermined depth position in the thickness direction of the first wafer, the laser beam is applied along a first circular projected processing line (street) located on an inner side by a predetermined distance than the peripheral edge of the wafer, whereby a first annular modified layer is formed.

Next, in a state in which the laser beam is concentrated at the same depth position, the laser beam is applied to an annular region between the first street and the peripheral edge of the wafer, along each of a plurality of second streets set radially, whereby a plurality of second modified layers in rectilinear form are formed. Then, the back surface side of the first wafer is ground, to thereby apply an external force to the first wafer. If cracks can be sufficiently extended, by this external force, with the first and second modified layers as starting points, it seems that the peripheral part of the first wafer can be removed with the first and second modified layers as a boundary.

### SUMMARY OF THE INVENTION

However, according to experiments conducted by the present applicant, it was found that, by only applying an external force by grinding of the back surface side, the degree of extension of cracks becomes insufficient and the annular region at the peripheral part may not be completely removed. The present invention has been made in consideration of such a problem. It is an object of the present invention to more securely remove an annular region of a peripheral part of a first wafer in a laminated wafer in which first and second wafers are laminated.

In accordance with an aspect of the present invention, there is provided a laminated wafer grinding method for grinding a laminated wafer in which a first surface of a first wafer and a third surface of a second wafer are laminated in a mutually facing state, the first wafer having the first surface and a second surface located on a side opposite to the first surface, peripheral parts on a side of the first surface and a side of the second surface being chamfered, the second wafer having the third surface and a fourth surface located on a side opposite to the third surface, peripheral parts on a side of the third surface and a side of the fourth surface being chamfered. The laminated wafer grinding method includes a modified layer forming step of applying a laser beam of such a wavelength as to be transmitted through the first wafer to the first wafer along a first annular street set on an inner side of a peripheral edge of the first wafer, to form a first annular modified layer inside the first wafer, and applying the laser beam to the first wafer along at least one second street set in an annular region extending from the first street to the peripheral edge of the first wafer, to form a second modified layer that partitions the annular region into two or more parts as the first surface is viewed in plan, a trimming step of causing a cutting blade to cut into the annular region to a predetermined depth in a thickness direction of the first wafer from the second surface, and relatively moving the laminated wafer and the cutting blade along the peripheral edge to cut the annular region, after the modified layer forming step, and a grinding step of grinding the side of the second surface of the first wafer to thin the first wafer to a finished thickness and removing the annular region, after the trimming step.

Preferably, in the trimming step, the annular region is cut in a state in which the predetermined depth to which the cutting blade is made to cut into is positioned below the first modified layer and the second modified layer.

In accordance with another aspect of the present invention, there is provided a laminated wafer grinding method for grinding a laminated wafer in which a first surface of a first wafer and a third surface of a second wafer are laminated in a mutually facing state, the first wafer having the first surface and a second surface located on a side opposite to the first surface, peripheral parts on a side of the first surface and a side of the second surface being chamfered, the second wafer having the third surface and a fourth surface located on a side opposite to the third surface, peripheral parts on a side of the third surface and a side of the fourth surface being chamfered. The laminated wafer grinding method includes a laser processed groove forming step of applying a laser beam of such a wavelength as to be absorbed in the first wafer from above the laminated wafer to the second surface of the first wafer along a first annular street set on an inner side of a peripheral edge of the first wafer, to form a first annular laser processed groove penetrating the first wafer in a thickness direction of the first wafer, and applying the laser beam from above the laminated wafer to the second surface along at least one third street set in an annular region extending from the first street to the peripheral edge of the first wafer, to form at least one second laser processed groove that partitions the annular region into two or more parts as the first surface is viewed in plan and that penetrates the first wafer in the thickness direction of the first wafer, a trimming step of causing a cutting blade to cut into the annular region to a predetermined thickness in the thickness direction of the first wafer from the second surface, and relatively moving the laminated wafer and the cutting blade along the peripheral edge, to cut the annular region, after the laser processed groove forming step, and a grinding step of grinding the side of the second surface of the first wafer to thin the first wafer to a finished thickness and removing the annular region, after the trimming step.

In the wafer grinding method according to an aspect of the present invention, the first modified layer is formed along the first annular street set on an inner side of the peripheral edge of the first wafer, and the second modified layer that divides, into two or more parts, the annular region extending from the first street to the peripheral edge of the first wafer is formed along at least one second street set in the annular region (modified layer forming step). After the modified layer forming step, the cutting blade is made to cut into the annular region to a predetermined depth in the thickness direction of the first wafer, to cut the annular region (trimming step). Further, after the trimming step, the second surface side of the first wafer is ground to thin the first wafer to the finished thickness, and the annular region is removed (grinding step).

In a case where the modified layer is formed in the annular region, if a load is directly applied to the annular region by the cutting blade in the trimming step, cracks extend to the front surface, whereby a bonding force between the annular region of the first wafer and the second wafer is lowered. Therefore, as compared to a case where the trimming step is not conducted, the annular region can be securely removed in the grinding step.

In addition, in the wafer grinding method according to another aspect of the present invention, the first laser processed groove penetrating the first wafer in the thickness direction of the first wafer is formed along the first annular street, and the second laser processed groove that divides, into two parts, the annular region extending from the first street to the peripheral edge of the first wafer along at least one third street set in the annular region and that penetrates the first wafer in the thickness direction of the first wafer is formed (processed groove forming step).

Further, after the processed groove forming step, the trimming step and the grinding step are sequentially conducted. In a case where the laser processed groove is formed in the annular region, when a load is directly applied to the annular region by the cutting blade in the trimming step, a bonding force between the annular region of the first wafer and the second wafer is lowered. Therefore, as compared to a case where the trimming step is not conducted, the annular region can be securely removed in the grinding step.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a sectional view of a laminated wafer;

FIG. 2 is a flow chart of a laminated wafer grinding method according to a first embodiment;

FIG. 3 is a plan view of the laminated wafer, in which first and second streets are depicted;

FIG. 4 is a diagram depicting the manner of forming a first modified layer;

FIG. 5 is a diagram depicting the manner of forming a second modified layer;

FIG. 6 is a diagram depicting a trimming step;

FIG. 7 is a diagram depicting a grinding step;

FIG. 8 is a flow chart of a laminated wafer grinding method according to a second embodiment;

FIG. 9 is a plan view of the laminated wafer, in which first and third streets are depicted; and

FIG. 10 is a sectional view taken along line C-C of FIG. 9 after a laser processed groove forming step.

### DETAILED DESCRIPTION OF THE PREFERRED EMBODIMENTS

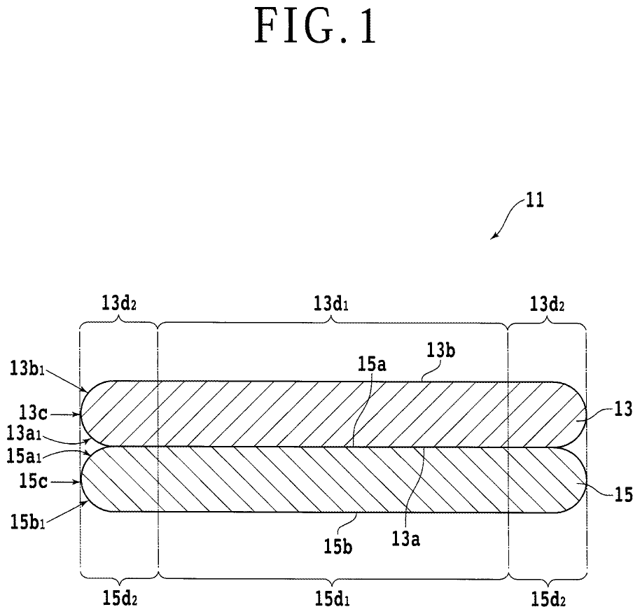

An embodiment according to one aspect of the present invention will be described referring to the attached drawings. First, referring to FIG. 1, a laminated wafer 11 as an object of processing such as grinding in each embodiment will be described. FIG. 1 is a sectional view of the laminated wafer 11. The laminated wafer 11 has a first wafer 13 and a second wafer 15 which are formed mainly of silicon (Si) and have substantially the same diameter. A peripheral part on a front surface (first surface) 13a side of the first wafer 13 is formed with a chamfered part 13a₁, and a peripheral part on a back surface (second surface) 13b side located on the side opposite to the front surface 13a is also formed with a chamfered part 13b₁. Similarly, a peripheral part on a front surface (third surface) 15a side of the second wafer 15 is formed with a chamfered part 15a₁, and a peripheral part on a back surface (fourth surface) 15b side located on the side opposite to the front surface 15a is also formed with a chamfered part 15b₁.

The first wafer 13 and the second wafer 15 are adhered to each other with a resin adhesive, in the state in which the front surfaces 13a and 15a face each other, such that the center of the front surface 13a and the center of the front surface 15a substantially coincide with each other. Therefore, a peripheral edge 13c of the first wafer 13 and a peripheral edge 15c of the second wafer 15 are substantially matched in the thickness direction of the laminated wafer 11. On the front surface 13a of the first wafer 13, a plurality of projected dicing lines (streets) are set in a grid pattern. In each of rectangular regions surrounded by the plurality of streets, a device (not illustrated) such as an IC and large scale integration (LSI) is formed.

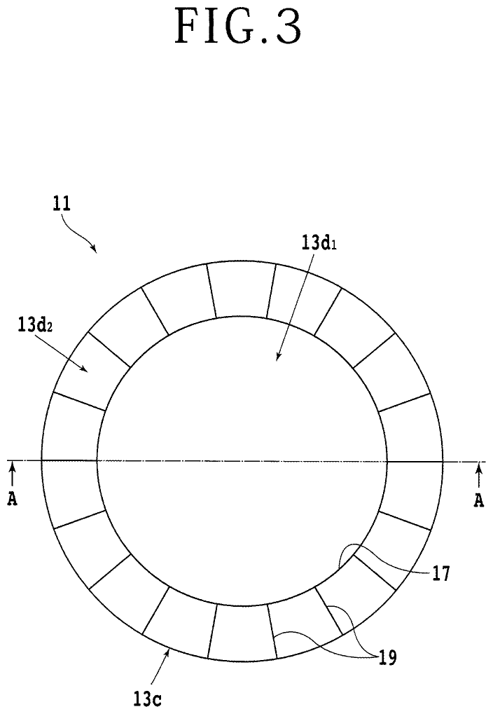

A circular area including a plurality of devices is called a device area 13d₁ (see FIGS. 1 and 3). Around the device area 13d₁, an annular peripheral marginal area (annular region) 13d₂ (see FIGS. 1 and 3) where no device is formed is present. Similarly, a plurality of streets are set in a grid pattern on the front surface 15a of the second wafer 15, and a device (not illustrated) is formed in each of rectangular regions surrounded by the plurality of streets. Also on the second wafer 15, an annular peripheral marginal area 15d₂ where no device is formed is present around an annular device area 15d₁ where a plurality of devices are formed.

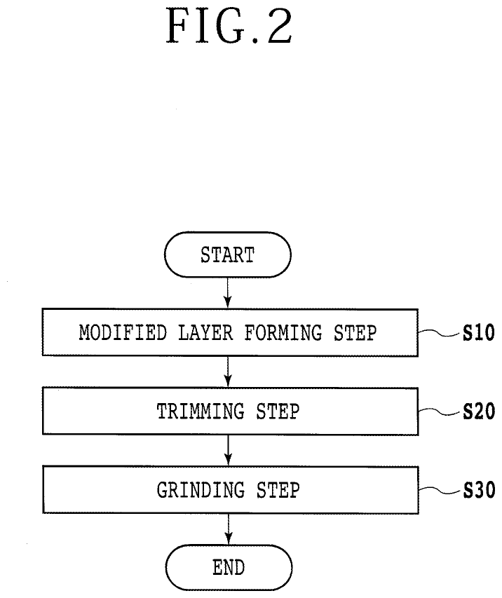

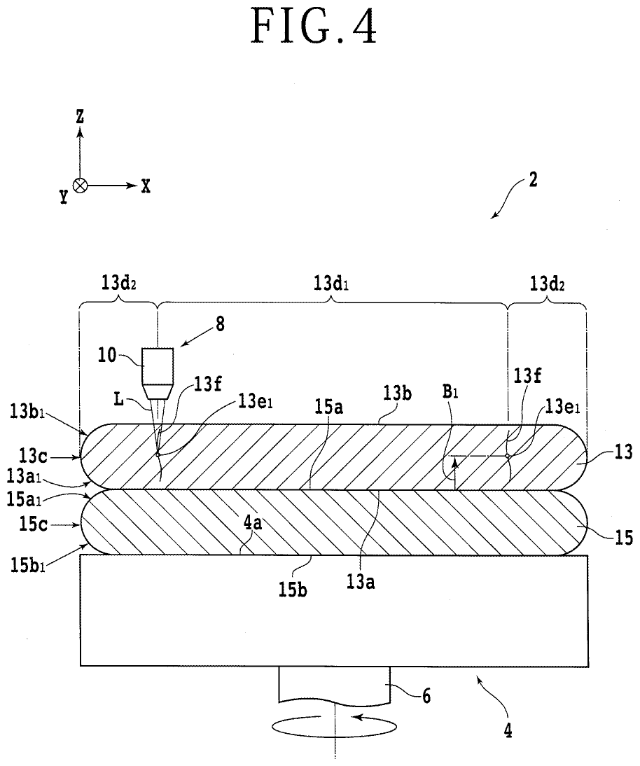

Next, a grinding method for the laminated wafer 11 in which the back surface 13b side of the first wafer 13 is ground to thin the laminated wafer 11 will be described. FIG. 2 is a flow chart of the grinding method for the laminated wafer 11 according to the first embodiment. In the first embodiment, first, by use of a laser processing apparatus 2, a plurality of modified layers are formed in the peripheral marginal area 13d₂ of the first wafer 13 (modified layer forming step S10). While referring to FIG. 4, the configuration of the laser processing apparatus 2 will be described.

A Z-axis direction depicted in FIG. 4 is, for example, a vertical direction, while an X-axis direction and a Y-axis direction are substantially parallel to horizontal directions. The laser processing apparatus 2 has a disk-shaped chuck table 4. The chuck table 4 has a disk-shaped frame body formed of metal. The frame body is formed in a central part thereof with a disk-shaped recess (not illustrated), and a disk-shaped porous plate is fixed in the recess. An upper surface of the frame body and an upper surface of the porous plate are substantially flush with each other, and a substantially flat holding surface 4a is formed.

The frame body is formed with a flow path, and one end of the flow path is connected to the porous plate. In addition, to the other end of the flow path, a suction source (not illustrated) such as an ejector is connected. When a negative pressure from the suction source is transmitted to the holding surface 4a, the laminated wafer 11 placed on the holding surface 4a is held under suction by the holding surface 4a. At a lower portion of the chuck table 4, a rotational drive source (not illustrated) such as a motor is disposed. Since a rotational axis 6 of the rotational drive shaft is connected to a lower portion of the chuck table 4, operation of the rotational drive source rotates the chuck table 4 around the rotational axis 6. The rotational drive source is supported by an X-axis direction moving plate (not illustrated).

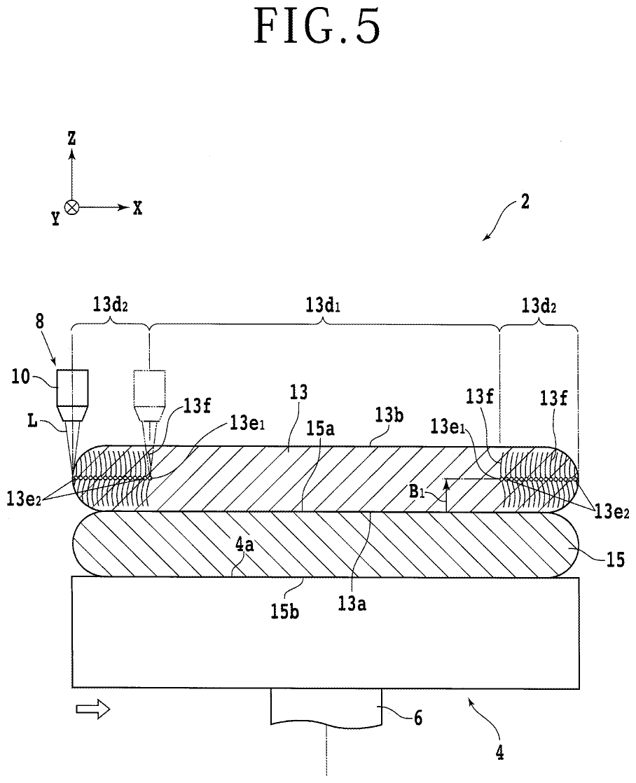

The X-axis direction moving plate is slidably supported by a pair of guide rails (not illustrated) substantially parallel to the X-axis direction. A nut section (not illustrated) is provided on a lower surface side of the X-axis direction moving plate, and a screw shaft (not illustrated) disposed substantially parallel to the X-axis direction is rotatably connected to the nut section through a ball (not illustrated). A drive source (not illustrated) such as a stepping motor is connected to one end part of the screw shaft, and, when the drive source is operated, the X-axis direction moving plate is moved in the X-axis direction together with the chuck table 4 (see FIG. 5). The X-axis direction moving plate, the guide rails, the screw shaft, and the like constitute an X-axis direction moving unit.

A laser beam applying unit 8 is disposed above the holding surface 4a. The laser beam applying unit 8 has a laser oscillator (not illustrated) and a light concentrating device 10 that includes a condenser lens (not illustrated) for condensing a laser beam L. Through the light concentrating device 10, a pulsed laser beam L having such a wavelength (for example, 1,064 nm) as to be transmitted through the first wafer 13 is applied from above the laminated wafer 11 to the back surface 13b. The laser beam L is concentrated at a predetermined depth position of the first wafer 13.

In the modified layer forming step S10, the laser beam L is applied along a first annular street 17 (see FIG. 3) that is located on the inner side by a predetermined distance in the radial direction of the first wafer 13 from the peripheral edge 13c and that is set at the boundary between the device area 13d₁ and the peripheral marginal area 13d₂. In the modified layer forming step S10, further, in the peripheral marginal area 13d₂ extending from the first street 17 to the peripheral edge 13c, the laser beam L is applied along at least one (in this example, 18) second street 19 (see FIG. 3) set radially at substantially regular intervals along the peripheral edge 13c.

FIG. 3 is a plan view of the laminated wafer 11, in which the first street 17 and the second streets 19 where the laser beam L is applied in the modified layer forming step S10 are depicted. In the modified layer forming step S10, first, the back surface 15b side of the second wafer 15 is held under suction by the holding surface 4a. Next, the light concentrating device 10 is disposed directly above the first street 17, and the light concentrating point of the laser beam L is positioned at a predetermined depth corresponding to a distance B₁ from the front surface 13a (see FIG. 4). In this state, the chuck table 4 is rotated. The processing conditions are set, for example, as follows.

Wavelength: 1,064 nm

Average output: 1 W

Repetition frequency: 100 kHz

Rotating speed: 180°/s

In the inside of the first wafer 13, multiphoton absorption is generated at the light concentrating point and in the vicinity thereof, so that a first annular modified layer 13e₁ is formed along the first street 17. FIG. 4 is a sectional view taken along line A-A of FIG. 3, and is a diagram depicting the manner in which the first modified layer 13e₁ is formed. In FIG. 4, the first modified layer 13e₁ is indicated by a circle for convenience′ sake. When the first modified layer 13e₁ is formed, cracks 13f extending, with the first modified layer 13e₁ as a starting point, to the front surface 13a and the back surface 13b are formed. It is to be noted, however, that at the time of the modified layer forming step S10, the cracks 13f may not necessarily reach the front surface 13a and the back surface 13b.

The distance B₁ is greater than a distance B₂ (described later), and a finished thickness B₃ (described later). For example, the distance B₁ is equal to or more than half the thickness of the first wafer 13 (that is, the distance between the front surface 13a and the back surface 13b), and, in a case where the thickness of the first wafer 13 is 775 μm, the distance B₁ is 700 μm. Note that in the present embodiment, one first annular modified layer 13e₁ is formed but two or more first modified layers 13e₁ may be formed by rotating the chuck table 4 in a state in which the light concentrating point is positioned at a depth different from the distance B₁.

After the first modified layer 13e₁ is formed, rotation of the chuck table 4 is stopped, and, in a state in which the light concentrating point is positioned at the distance B₁ from the front surface 13a, the chuck table 4 is moved in the X-axis direction by the X-axis moving unit, whereby a second modified layer 13e₂ is formed along one second street 19. The processing conditions are set, for example, as follows.

Wavelength: 1,064 nm

Average output: 1 W

Repetition frequency: 100 kHz

Feeding speed: 800 mm/s

As a result, at a depth position of the distance B₁ from the front surface 13a, the first modified layer 13e₁ and the second modified layer 13e₂ are formed. FIG. 5 is a diagram depicting the manner in which the second modified layer 13e₂ is formed. In FIG. 5, one second modified layer 13e₂ formed at the distance B₁ from the front surface 13a along one second street 19 is depicted by a plurality of circles for the convenience′ sake.

In a case where the front surface 13a is viewed in plan, the first wafer 13 is partitioned into two parts in the circumferential direction of the first wafer 13 by the one second modified layer 13e₂. As depicted in FIG. 3, the peripheral marginal area 13d₂ of the present embodiment is partitioned into 18 parts by the 18 second street 19. When the second modified layer 13e₂ is formed, cracks 13f extending, with the second modified layer 13e₂ as a starting point, to the front surface 13a and the back surface 13b are also formed. The cracks 13f are indicated by wavy line for convenience′ sake in FIG. 5, but, at the time of the modified layer forming step S10, the cracks 13f may not necessarily reach the front surface 13a and the back surface 13b.

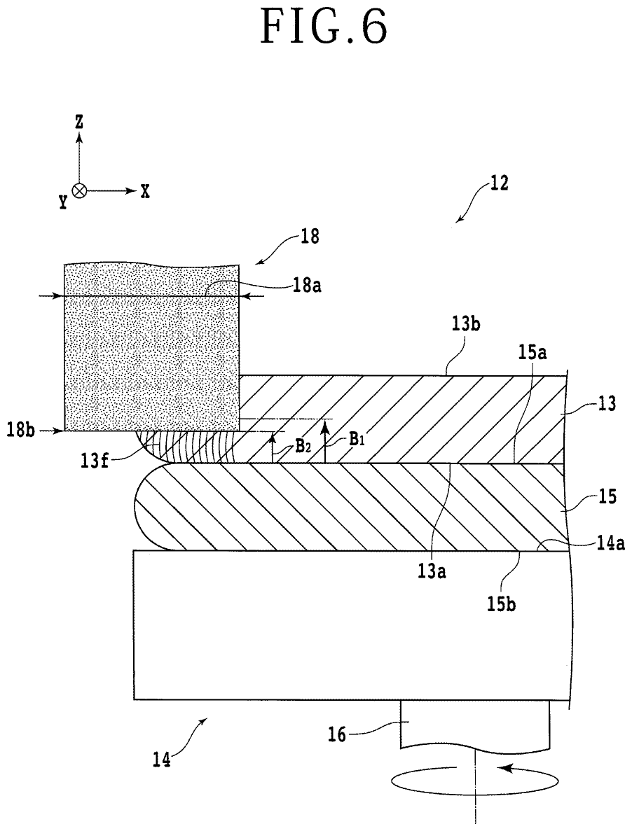

After the modified layer forming step S10, the back surface 13b side of the peripheral marginal area 13d₂ is cut by use of a cutting apparatus 12 (trimming step S20). FIG. 6 is a diagram depicting the trimming step S20. The cutting apparatus 12 has a disk-shaped chuck table 14. The configuration of the chuck table 14 is substantially the same as that of the above-mentioned chuck table 4, but the frame body of the chuck table 14 is not formed of metal but formed of resin. A rotational shaft 16 of a rotational drive source (not illustrated) such as a motor is connected to a lower portion of the chuck table 14. A cutting unit is provided above the chuck table 14. The cutting unit has a cylindrical spindle (not illustrated).

The height direction, i.e. the longitudinal direction, of the spindle is disposed substantially parallel to a horizontal direction. A rotational drive source such as a motor is provided at one end part of the spindle, and a cutting blade 18 is attached at the other end part of the spindle. The cutting blade 18 has a comparatively large cutting edge thickness 18a. The cutting edge thickness 18a is larger than the distance from the first street 17 to the peripheral edge 13c (that is, the width of the peripheral marginal area 13d₂). The cutting edge thickness 18a of the present embodiment is 3 mm, and the width of the peripheral marginal area 13d₂ is 2 mm.

In the trimming step S20, first, the back surface 15b side of the second wafer 15 is held under suction by the holding surface 14a. In this instance, the back surface 13b of the first wafer 13 is exposed to the upper side. Next, the spindle is rotated at high speed (for example, 20,000 rpm), and the cutting blade 18 is made to cut into the peripheral marginal area 13d₂. Specifically, the cutting blade 18 is made to cut into the peripheral marginal area 13d₂ such that a lower end 18b of the cutting blade 18 is positioned at a predetermined depth corresponding to the distance B₂ from the front surface 13a in the thickness direction of the first wafer 13.

The distance B₂ (herein also referred to as a cut residual thickness) is smaller than the above-mentioned distance B₁. In other words, in the trimming step S20, the lower end 18b of the cutting blade 18 is positioned below the first modified layer 13e₁ and the second modified layer 13e₂. In a state in which the lower end 18b is made to cut into a predetermined depth, the chuck table 14 is rotated at a predetermined rotating speed, whereby the first wafer 13 is moved relative to the cutting blade 18 along the peripheral edge 13c. In the present embodiment, the chuck table 14 is rotated by 2°/s (that is, 120°/min), whereby the chuck table 14 is caused to make one rotation in three minutes, and the peripheral marginal area 13d₂ on the back surface 13b side is removed.

In the trimming step S20, a load can be directly exerted on the peripheral marginal area 13d₂. Therefore, the cracks 13f with the first modified layer 13e₁ and the second modified layer 13e₂ as starting points can be securely extended in such a manner as to reach the front surface 13a. In addition, by the trimming step S20, the second modified layer 13e₂ is removed. Therefore, as compared to a case where the second modified layer 13e₂ is left, the flexural strength of the device chips manufactured from the laminated wafer 11 can be enhanced.

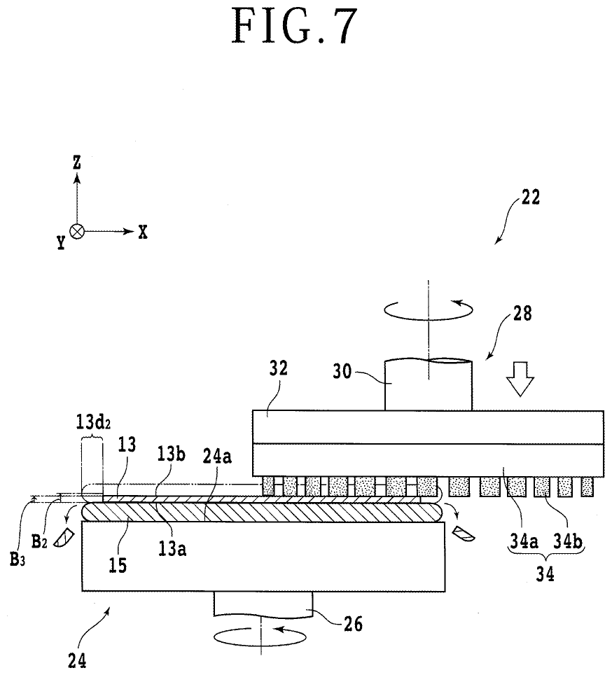

After the trimming step S20, the back surface 13b side of the first wafer 13 is ground by use of a cutting apparatus 22 (grinding step S30). As depicted in FIG. 7, the cutting apparatus 22 has a disk-shaped chuck table 24. The chuck table 24 has a disk-shaped frame body formed of a nonporous ceramic. The frame body is formed in a central portion thereof with a disk-shaped recess (not illustrated), and a disk-shaped porous plate is fixed in the recess. An upper surface of the frame body and an upper surface of the porous plate are substantially flush with each other and the upper surfaces make a holding surface 24a. The holding surface 24a has a conical shape in which a central portion is slightly projected as compared with a peripheral portion.

The frame body is formed with a flow path, and one end of the flow path is connected to a porous plate. In addition, a suction source (not illustrated) such as an ejector is connected to the other end of the flow path, and a negative pressure from the suction source is transmitted to the holding surface 24a. A rotational axis 26 of a rotational drive source (not illustrated) such as a motor is connected to a lower portion of the chuck table 24. The rotational axis 26 is inclined by an inclination adjusting mechanism (not illustrated) such that a part of the conical holding surface 24a is substantially parallel to a horizontal surface.

A grinding unit 28 is disposed on the upper side of the holding surface 24a. The grinding unit 28 has a cylindrical spindle 30 disposed substantially parallel to the Z-axis direction. A motor is provided at an upper end portion of the spindle 30, and a disk-shaped mount 32 is fixed to a lower end portion of the spindle 30. An annular grinding wheel 34 is mounted to a lower surface side of the mount 32. The grinding wheel 34 has an annular wheel base 34a made of metal. On the lower surface side of the wheel base 34a, a plurality of block-shaped grindstones 34b are disposed at predetermined intervals along the circumferential direction of the wheel base 34a.

FIG. 7 is a diagram depicting the grinding step S30. In the grinding step S30, first, the back surface 15b side of the second wafer 15 is held under suction by the holding surface 24a. In this instance, the back surface 13b of the first wafer 13 is exposed to the upper side. Next, the chuck table 24 and the grinding wheel 34 are rotated, and the grinding wheel 34 is lowered at a predetermined grinding feeding speed. A grinding surface defined by a lower surfaces of the plurality of grindstones makes contact with the back surface 13b, whereby the back surface 13b side of the first wafer 13 is ground, and the first wafer 13 is thinned to the finished thickness B₃. In this instance, the first modified layer 13e₁ is removed from the first wafer 13. Note that the distance between the front surface 13a and the back surface 13b that has undergone the grinding step S30, the distance corresponding to the finished thickness B₃, is smaller than the distance B₁ where the first modified layer 13e₁ or the like is formed and the distance B₂ corresponding to the cut residual thickness.

Since the cracks 13f reach the front surface 13a through the trimming step S20 in the peripheral marginal area 13d₂, the bonding force between the peripheral marginal area 13d₂ on the front surface 13a side of the first wafer 13 and the peripheral marginal area 15d₂ on the front surface 15a side of the second wafer 15 is lowered. Therefore, in the grinding step S30, the peripheral marginal area 13d₂ is divided by an external force such as a centrifugal force and vibration, and is removed from the laminated wafer 11.

Thus, in the present embodiment, since the peripheral marginal area 13d₂ is formed with the first modified layer 13e₁ and the second modified layer 13e₂, when a load is directly exerted on the peripheral marginal area 13d₂ in the trimming step S20, the cracks 13f extend and securely reach the front surface 13a. As a result, the bonding force between the peripheral marginal area 13d₂ of the first wafer 13 and the second wafer 15 is lowered. Therefore, as compared to a case where the trimming step S20 is not conducted, the peripheral marginal area 13d₂ can be securely removed in the grinding step S30.

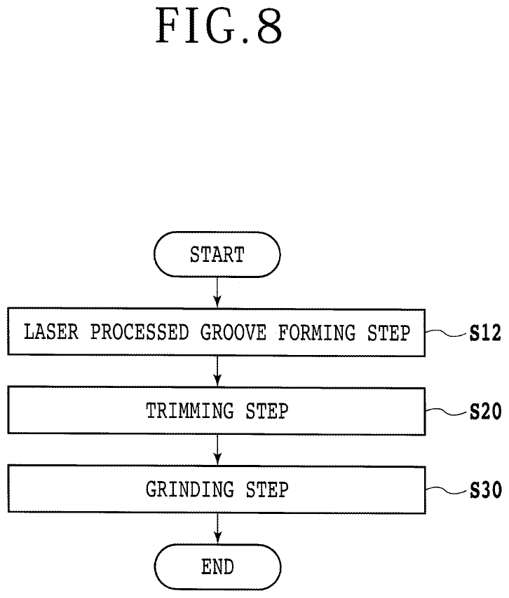

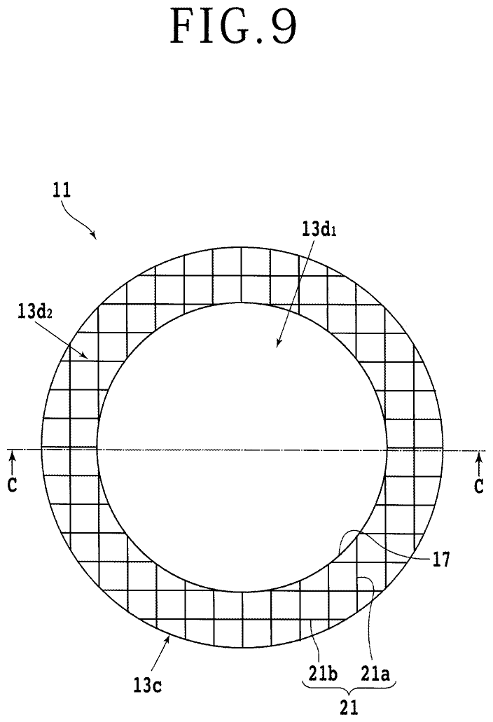

Next, a second embodiment will be described. FIG. 8 is a flow chart of the grinding method for the laminated wafer 11 according to the second embodiment. In the second embodiment, a laser processed groove forming step S12 is conducted in place of the modified layer forming step S10. In the second embodiment, a first annular street 17 which is the same as that in the first embodiment is set, but a plurality of third streets 21 different from that in the first embodiment are set in a grid pattern in the peripheral marginal area 13d₂ (see FIG. 9).

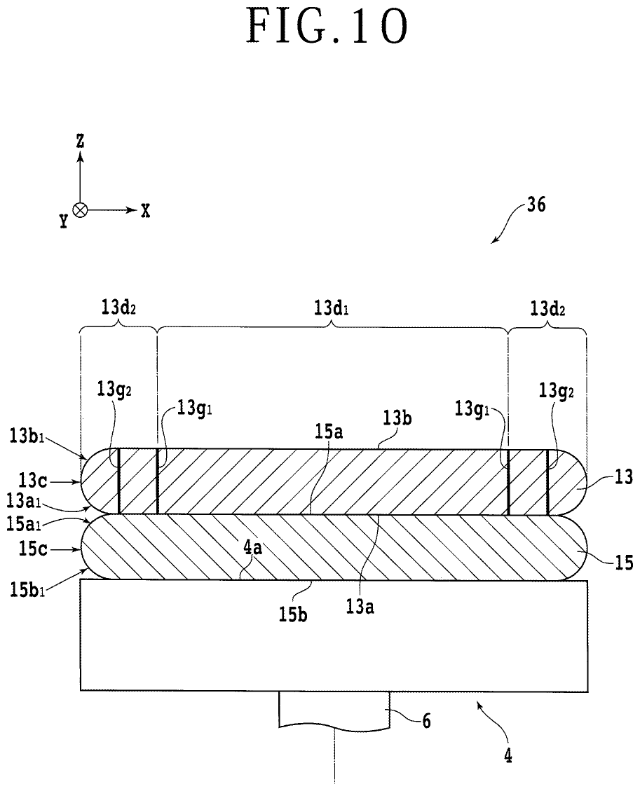

FIG. 9 is a plan view depicting the laminated wafer 11, in which the first street 17 and the third streets 21 are depicted. In addition, FIG. 10 is a sectional view taken along line C-C of FIG. 9 after the laser processed groove forming step S12. In the laser processed groove forming step S12, the first wafer 13 is processed by use of a laser processing apparatus 36 (see FIG. 10) that is substantially similar to the laser processing apparatus 2 depicted in FIG. 4 but applies a pulsed laser beam of such a wavelength (for example, 355 nm) as to be absorbed in the first wafer 13.

The laser processing apparatus 36 has, in addition to the chuck table 4, the rotational drive source, and the X-axis direction moving unit, a Y-axis direction moving plate (not illustrated) that is provided on the X-axis direction moving plate and that supports the rotational drive source. The Y-axis direction moving plate is slidably attached onto a pair of guide rails (not illustrated) disposed substantially parallel to the Y-axis direction and fixed on the X-axis direction moving plate. A nut section (not illustrated) is provided on a lower surface side of the Y-axis direction moving plate, and a screw shaft (not illustrated) disposed substantially parallel to the Y-axis direction is connected to the nut section rotatably through a ball (not illustrated). A drive source (not illustrated) such as a stepping motor is connected to one end portion of the screw shaft.

When the drive source is operated, the Y-axis direction moving plate is moved in the Y-axis direction together with the chuck table 4. The Y-axis direction moving plate, the guide rails, the screw shaft, and the like constitute a Y-axis direction moving unit. Note that in FIG. 10, the laser beam applying unit 8 is omitted. In the laser processed groove forming step S12, specifically, first, in a state in which a laser beam is applied from above the laminated wafer 11 to the back surface 13b along the first street 17, the chuck table 4 is rotated. The processing conditions are set, for example, as follows. As a result, a first annular laser processed groove 13g₁ penetrating the first wafer 13 in the thickness direction of the first wafer 13 is formed (see FIG. 10).

Wavelength: 355 nm

Average output: 1 W

Repetition frequency: 100 kHz

Rotating speed: 180°/s

Next, by rotating the chuck table 4 such that a third street 21a parallel to the first direction, of the plurality of third streets 21, becomes substantially parallel to the X-axis direction, the orientation of the laminated wafer 11 is adjusted. Then, the laser beam is applied along one third street 21a by the X-axis direction moving unit, whereby a second laser processed groove 13g₂ is formed. The processing conditions are set, for example, as follows.

Wavelength: 355 nm

Average output: 1 W

Repetition frequency: 100 kHz

Processing feeding speed: 800 mm/s

After the second laser processed groove 13g₂ is formed along one third street 21a, the application position of the laser beam is modified by the Y-axis direction moving unit, and the laser beam is applied along another third street 21a adjacent to the one third street 21a. Note that the application timing of the laser beam is adjusted as required such that the second laser processed groove 13g₂ is formed only in the peripheral marginal area 13d₂ but that the second laser processed groove 13g₂ is not formed in the device area 13d₁.

After the second laser processed grooves 13g₂ are formed along all the third streets 21a parallel to the first direction, the second laser processed grooves 13g₂ are similarly formed along all third streets 21b parallel to the second direction orthogonal to the first direction by use of the Y-axis direction moving unit. In the present embodiment, the second laser processed grooves 13g₂ are formed along 13×13 third streets 21a that orthogonally intersect each other, but the number of the third streets 21 is not limited to this.

The third streets 21a may be 10×10 streets that orthogonally intersect each other, or may be 20×20 streets that orthogonally intersect each other. Note that in the present embodiment, the third streets 21 that coincide with each other when the streets are elongated across the device area 13d₁ are counted as one. It is sufficient if when the front surface 13a is viewed in plan, the peripheral marginal area 13d₂ can be divided into two or more parts by at least one third street 21. It is to be noted that the number of third streets 21 that divide the peripheral marginal area 13d₂ is more preferable to be larger, since the bonding force between the peripheral marginal area 13d₂ of the first wafer 13 and the second wafer 15 is liable to be lowered.

In the second embodiment, in the trimming step S20 after the laser processed groove forming step S12, when a load is directly exerted on the peripheral marginal area 13d₂ by the cutting blade 18, the bonding force between the peripheral marginal area 13d₂ of the first wafer 13 and the second wafer 15 is lowered. Therefore, as compared to a case where the trimming step S20 is not conducted, the annular region can be securely removed by the grinding step S30.

Other than the above, the structures, methods, and the like according to the above-mentioned embodiment can be modified in carrying out the present invention insofar as not to depart from the scope of the object of the invention. In the first embodiment, a plurality of second streets 19 are set radially, but, like the second embodiment, one or more second streets 19 may be set in a grid pattern. In addition, in the second embodiment, like in the first embodiment, one or more third streets 21 may be set radially. Incidentally, in the modified layer forming step S10, the first modified layer 13e₁ may be formed after the second modified layer 13e₂ is formed. In addition, also in the laser processed groove forming step S12, the first laser processed groove 13g₁ may be formed after the second laser processed groove 13g₂ is formed.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A laminated wafer grinding method for grinding a laminated wafer in which a first surface of a first wafer and a third surface of a second wafer are laminated in a mutually facing state, the first wafer having the first surface and a second surface located on a side opposite to the first surface, peripheral parts on a side of the first surface and a side of the second surface being chamfered, the second wafer having the third surface and a fourth surface located on a side opposite to the third surface, peripheral parts on a side of the third surface and a side of the fourth surface being chamfered, the laminated wafer grinding method comprising:
a modified layer forming step of applying a laser beam of such a wavelength as to be transmitted through the first wafer to the first wafer along a first annular street set on an inner side of a peripheral edge of the first wafer, to form a first annular modified layer inside the first wafer, and applying the laser beam to the first wafer along at least one second street set in an annular region extending from the first street to the peripheral edge of the first wafer, to form a second modified layer that partitions the annular region into two or more parts as the first surface is viewed in plan;
a trimming step of causing a cutting blade to cut into the annular region to a predetermined depth in a thickness direction of the first wafer from the second surface, and relatively moving the laminated wafer and the cutting blade along the peripheral edge to cut the annular region, after the modified layer forming step; and
a grinding step of grinding the side of the second surface of the first wafer to thin the first wafer to a finished thickness and removing the annular region, after the trimming step.

2. The laminated wafer grinding method according to claim 1, wherein, in the trimming step, the annular region is cut in a state in which the predetermined depth to which the cutting blade is made to cut into is positioned below the first modified layer and the second modified layer.

3. A laminated wafer grinding method for grinding a laminated wafer in which a first surface of a first wafer and a third surface of a second wafer are laminated in a mutually facing state, the first wafer having the first surface and a second surface located on a side opposite to the first surface, peripheral parts on a side of the first surface and a side of the second surface being chamfered, the second wafer having the third surface and a fourth surface located on a side opposite to the third surface, peripheral parts on a side of the third surface and a side of the fourth surface being chamfered, the laminated wafer grinding method comprising:
a laser processed groove forming step of applying a laser beam of such a wavelength as to be absorbed in the first wafer from above the laminated wafer to the second surface of the first wafer along a first annular street set on an inner side of a peripheral edge of the first wafer, to form a first annular laser processed groove penetrating the first wafer in a thickness direction of the first wafer, and applying the laser beam from above the laminated wafer to the second surface along at least one third street set in an annular region extending from the first street to the peripheral edge of the first wafer, to form at least one second laser processed groove that partitions the annular region into two or more parts as the first surface is viewed in plan and that penetrates the first wafer in the thickness direction of the first wafer;
a trimming step of causing a cutting blade to cut into the annular region to a predetermined thickness in the thickness direction of the first wafer from the second surface, and relatively moving the laminated wafer and the cutting blade along the peripheral edge, to cut the annular region, after the laser processed groove forming step; and
a grinding step of grinding the side of the second surface of the first wafer to thin the first wafer to a finished thickness and removing the annular region, after the trimming step.
